(19) United States
(12) Patent Application Publication
(10) Pub. No.: US 2010/0073071 A1
(43) Pub. Date: Mar. 25, 2010

(54) Over-temperature detecting circuit with high precision

(76) Inventors: Mao-Chuan Chien, Taipei County (TW); Shun-Hau Kao, Taipei County (TW)

Correspondence Address: NORTH AMERICA INTELLECTUAL PROPERTY CORPORATION, P.O. BOX 506, MERRIFIELD, VA, 22116, US

(21) Appl. No.: 12/275,228

(22) Filed: Nov. 21, 2008

(30) Foreign Application Priority Data
Sep. 25, 2008 (TW) 097136830

(51) Int. Cl. H01L 37/00

(52) U.S. Cl. 327/513

(57) ABSTRACT

An over-temperature detecting circuit includes a band-gap circuit for generating a temperature-drop-dependent voltage and a reference voltage not varying with the temperature, a transistor coupled to the band-gap circuit for generating a temperature-rise-dependent current according to the temperature-drop-dependent voltage, a resistor coupled to the transistor for generating a temperature-rise-dependent voltage according to the temperature-rise-dependent current, and a comparator coupled to the band-gap circuit and the resistor for generating a thermal shutdown signal according to the reference voltage and the temperature-rise-dependent voltage.

### BACKGROUND OF THE INVENTION

1. Field of the Invention

The present invention relates to an over-temperature detecting circuit, and more particularly, to an over-temperature detecting circuit capable of accurately detecting the upper limit of temperature to trigger a thermal shutdown signal to shut relevant circuits for protection.

2. Description of the Prior Art

Please refer to FIG. 1. FIG. 1 is a diagram of an over-temperature detecting circuit 100 in the prior art. The over-temperature detecting circuit 100 is utilized to detect the temperature and generate a thermal shutdown signal V_{TH1} in accordance. When the temperature is lower than a predetermined temperature upper limit T_{S1}, the thermal shutdown signal V_{TH1} remains at a high voltage level (V_{H}); while the thermal shutdown signal V_{TH1} reduces to a low voltage level (V_{L}) when the temperature exceeds the temperature upper limit T_{S1}. The relevant circuit is shut down to prevent the components from destruction when the thermal shutdown signal V_{TH1} is detected at the low voltage level.

As illustrated in FIG. 1, the over-temperature detecting circuit 100 comprises a first and a second reference current sources I_{REF}, transistors Q₁, Q₂ and Q₃, and a resistor R_{X}. The transistor Q₁ is a PNP bipolar junction transistor (BJT). The transistors Q₂ and Q₃ are N-channel metal oxide semiconductor (NMOS) transistors. Intrinsically, the base-emitter voltage V_{BE1} of the BJT transistor Q₁ decreases when the temperature increases gradually. Therefore, the base-emitter voltage V_{BE1} of the transistor Q₁ may be represented by: V_{BE1}(T)=V_{BE10}+KT, wherein T represents the temperature, V_{BE10} represents the initial value of the base-emitter voltage V_{BE1} of the transistor Q₁, and K represents a constant. The voltage V_{X1} does not change according to the temperature when the first and the second reference current sources I_{REF} are well biased. Hence it is necessary to carefully design the value of the reference current sources I_{REF} and the resistor R_{X} in the circuit of FIG. 1. As so, when the temperature is lower than the temperature upper limit T_{S1}, wherein the base-emitter voltage V_{BE1} is higher in this range, the voltage V_{X1} is unable to turn on the transistor Q₂. Therefore, the thermal shutdown signal V_{TH1} then remains at the high voltage level (V_{H}). On the contrary, when the temperature exceeds the temperature upper limit T_{S1}, wherein the base-emitter voltage V_{BE1} is lower in this range, the voltage V_{X1} is then able to turn on the transistor Q₂ and the thermal shutdown signal V_{TH1} is dragged to the low voltage level (V_{L}). In this way, it is practicable to utilize the over-temperature detecting circuit 100 to determine when to drag the thermal shutdown signal V_{TH1} to the low voltage level (V_{L}). The way that the transistor Q₂ turns on may be represented by the inequality (1) as follows:

V_{X1}>V_{GSQ2}+V_{BE1}(T)=V_{GSQ2}+V_{BE10}+KT (1);

wherein V_{GSQ2} represents the threshold voltage of the transistor Q₂. The values of the voltages V_{X1}, V_{GSQ2} and V_{BE1}(T) may be well designed such that the inequality (1) is true when the temperature meets the temperature upper limit T_{S1}:

V_{X1}>V_{GSQ2}+V_{BE1}+KT_{S1} (2).

Please refer to FIG. 2. FIG. 2 is a diagram illustrating the relation between the thermal shutdown signal in the over-temperature detecting circuit 100 in the prior art and the temperature. As illustrated in FIG. 2, when the temperature is lower than the temperature upper limit T_{S1}, the base-emitter voltage V_{BE1} is higher, the transistor Q₂ is not turned on, and the thermal shut down signal V_{TH1} remains at the high voltage level (V_{H}). However, when the temperature exceeds the temperature upper limit T_{S1}, the base-emitter voltage V_{BE1} decreases such that the voltage V_{X1} is able to turn on the transistor Q₂, and drag the thermal shut down signal V_{TH1} down to the low voltage level (V_{L}).

However, the threshold voltage of the transistor may vary depending on the fabrication process. That is, in inequity (1), the threshold voltage V_{GSQ2} is not independent of the fabrication process but may drift due to different fabrication processes. Therefore, the inequity (2) may be true only under certain base-emitter voltage V_{BE1} (T) at other temperature as desired, such like T_{S3}. And the inequity (2) then becomes: V_{X1}>V_{GSQ2}+V_{BE10}+KT_{S3}. Hence the temperature at which the over-temperature detecting circuit 100 determines to shut down the relevant circuit may drift from the predetermined temperature upper limit T_{S1}, and the relevant circuit may not be shut down timely and consequently be the destroyed.

### SUMMARY OF THE INVENTION

The present invention discloses an over-temperature detecting circuit. The over-temperature detecting circuit comprises a band-gap circuit for generating a temperature-drop-dependent voltage and a reference voltage not varying with the temperature, a transistor coupled to the band-gap circuit for generating a temperature-rise-dependent current according to the temperature-drop-dependent voltage, a resistor coupled to the transistor for generating a temperature-rise-dependent voltage according to the temperature-rise-dependent current, and a comparator coupled to the band-gap circuit and the resistor for generating a thermal shutdown signal according to the reference voltage and the temperature-rise-dependent voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an over-temperature detecting circuit in the prior art.

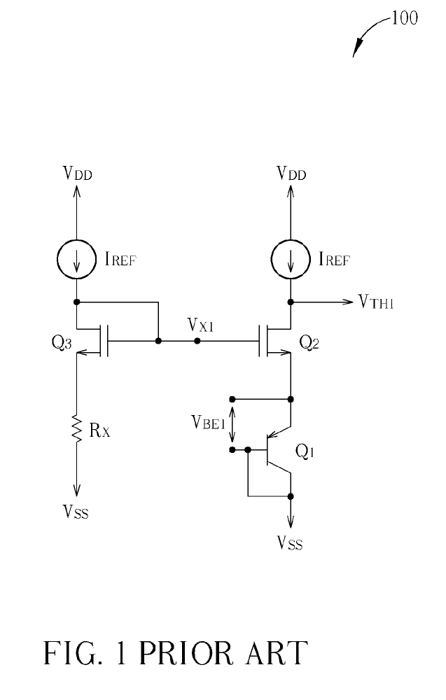

FIG. 2 is a diagram illustrating the relation between the thermal shutdown signal in the over-temperature detecting circuit in the prior art and the temperature.

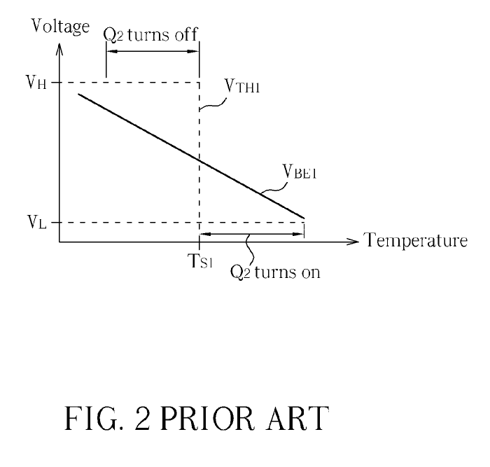

FIG. 3 is a diagram of an over-temperature detecting circuit of the present invention.

FIG. 4 is a diagram illustrating the relation of the temperature-rise-dependent voltage, the reference voltage and the thermal shutdown signal.

### DETAILED DESCRIPTION

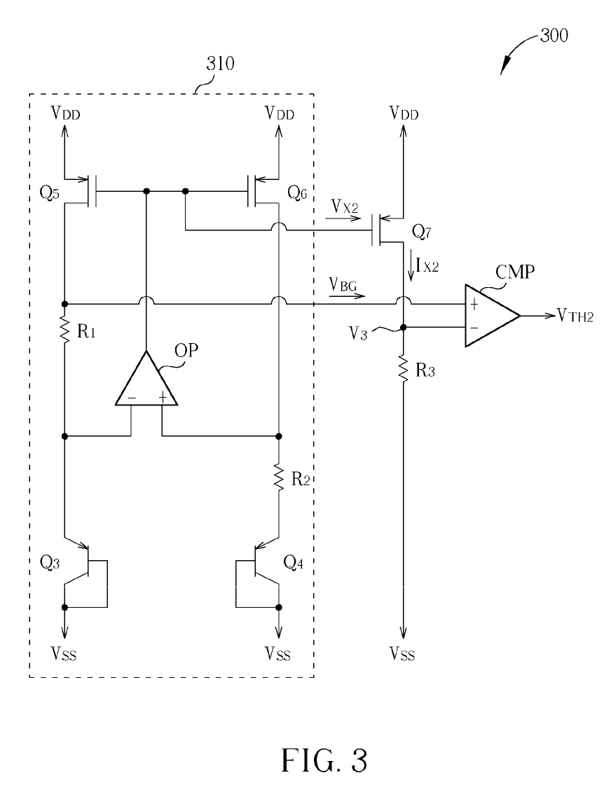

Please refer to FIG. 3. FIG. 3 is a diagram of an over-temperature detecting circuit 300 of high accuracy of the present invention. As illustrated in FIG. 3, the over-temperature detecting circuit 300 comprises a band-gap circuit 310, a transistor Q₇, a resistor R₃, and a comparator CMP. The transistor Q₇ is a P-channel metal oxide semiconductor (PMOS) transistor.

The band-gap circuit 310 is utilized to provide a temperature-drop-dependent voltage V_{X2} and a reference voltage V_{BG}. The temperature-drop-dependent voltage V_{X2} decreases along with the increase of the temperature, while the reference voltage V_{BG} does not vary along with the temperature. The temperature-drop-dependent voltage V_{X2} may be represented by: V_{X2}(T)=V_{X20}−MT, wherein T represents the temperature, V_{X20} represents the initial value of the temperature-declining voltage V_{X2}, and M represents a constant.

The control end, i.e. the gate, of the transistor Q₇ is for receiving the temperature-drop-dependent voltage V_{X2}, the first end, i.e. the source, of the transistor Q₇ is for receiving the bias source V_{DD}, and the second end, i.e. the drain, of the transistor Q₇ is coupled to the resistor R₃. The transistor Q₇ generates the temperature-rise-dependent current I_{X2} according to the temperature-drop-dependent voltage V_{X2}. For the temperature-drop-dependent voltage V_{X2} decreases along with the increase of the temperature, the gate-source voltage of the transistor Q₇ increases by [V_{DD}−V_{X2}(T)=V_{DD}−V_{X20}+MT] in accordance. That is, the temperature-rise-dependent current I_{X2} increases along with the temperature. The temperature-rise-dependent current I_{X2} flows along the resistor R₃ such that the temperature-rise-dependent voltage V₃ crossing the resistor R₃ increases along with the temperature as well.

The comparator CMP comprises a positive input, a negative input and an output. The positive input of the comparator CMP is coupled to the band-gap circuit 310 for receiving a reference voltage V_{BG}. The negative input of the comparator CMP is coupled to the resistor R₃ for receiving the temperature-rise-dependent voltage V₃. The output of the comparator CMP is for outputting the thermal shutdown signal V_{TH2}. When the voltage V₃ is lower than the reference voltage V_{BG}, the comparator CMP outputs the thermal shutdown signal V_{TH2} at the high voltage level (V_{H}) to represent that the temperature has not reached the temperature upper limit T_{S2}, and the relevant circuit coupled to the over-temperature detecting circuit 300 is able to remain normal operation and does not need to be shut down. On the contrary, when the temperature-rise-dependent voltage V₃ exceeds the reference voltage V_{BG}, the comparator CMP outputs the thermal shutdown signal V_{TH2} at the low voltage level (V_{L}) to represent that the temperature has reached the temperature upper limit T_{S2} and the relevant circuit needs to be shut down.

The band-gap circuit 310 comprises four transistors Q₃, Q₄, Q₅ and Q₆, two resistors R₁ and R₂, and an operational amplifier OP. The transistors Q₃ and Q₄ are PNP bipolar junction transistors, and the transistors Q₅ and Q₆ are PMOS transistors. The structure of internal components of the band-gap circuit 310 is illustrated as follows.

The base of the transistor Q₃ is coupled to the collector of the transistor Q₃. The collector of the transistor Q₃ is coupled to a bias source V_{SS} (ground). The emitter of the transistor Q₃ is coupled to the negative input of the operational amplifier OP and the resistor R₁. The base of the transistor Q₄ is coupled to the collector of the transistor Q₄. The collector of the transistor Q₄ is coupled to the bias source V_{SS} (ground). The emitter of the transistor Q₄ is coupled to resistor R₂. The resistor R₂ is coupled to the emitter of the transistor Q₄, the positive input of the operational amplifier OP and the drain of the transistor Q₆. The resistor R₁ is coupled to the negative input of the operational amplifier OP, the drain of the transistor Q₅ and the emitter of the transistor Q₃. The source of the transistor Q₅ is coupled to the bias source V_{DD}. The gate of the transistor Q₅ is coupled to the output of the operational amplifier OP. The drain of the transistor Q₅ is coupled to the resistor R₁. For the transistor Q₆, the source is coupled to the bias source V_{DD}, the gate is coupled to the output of the operational amplifier OP, and the drain is coupled to the resistor R₂. The operation principle of the band-gap circuit 310 is well known to the people skilled in the art, and is not described here for conciseness. The band-gap circuit 310 takes the drain of the transistor Q₅, or an end of the resistor R₁, as an output for outputting the reference voltage V_{BG} which does not vary with the temperature. The band-gap circuit 310 takes the output of the operational amplifier OP as another output for outputting the temperature-drop-dependent voltage V_{X2} which decreases along with the increase of the temperature.

Besides, in the band-gap circuit 310, the transistors Q₅ and Q₆ are PMOS transistors, while the transistors Q₃ and Q₄ are PNP bipolar junction transistors.

Dependence of the temperature-drop-dependent voltage V_{X2} on temperature variation does not change in different fabrication processes. Similarly, the dependence of the deduced temperature-rise-dependent voltage V₃ does not change in different fabrication processes as well. Therefore, when the reference voltage V_{BG} is stationary, the comparator CMP is able to accurately determine when the temperature reaches the temperature upper limit T_{S2} according to the temperature-rise-dependent voltage V₃, so as to generate the thermal shutdown signal V_{TH2} at the low voltage level.

Besides, the bias voltage output from the bias source V_{DD} is higher than the bias voltage output from the bias source V_{SS}.

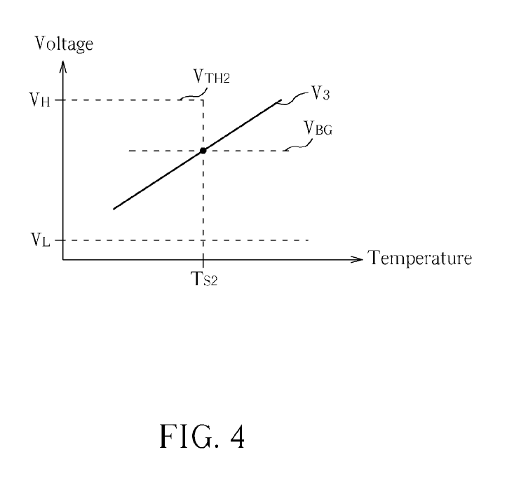

Please refer to FIG. 4. FIG. 4 is a diagram illustrating the relation of the temperature-rise-dependent voltage, the reference voltage and the thermal shutdown signal. As illustrated by FIG. 4, since the reference voltage V_{BG} is stationary, and the dependence of the temperature-rise-dependent voltage V₃ on temperature variation does not change in different processes, such as slope or initial voltage, it is ensured that when the reference voltage V_{BG} and the temperature-rise-dependent voltage V₃ have been set, the criterion by which the comparator CMP determines to pull the thermal shutdown signal V_{TH2} from the high voltage level (V_{H}) down to the low voltage level (V_{L}) may be accurately set to the required temperature upper limit T_{S2}. In this way, the problem of inaccuracy of the determination of the temperature upper limit due to the different fabrication processes in the prior art may be resolved.

To sum up, the high-precision over-temperature detecting circuit of the present invention may accurately determine when the temperature is over-high to output the thermal shutdown signal and shut down the relevant circuit, which decreases the damage of the relevant circuit caused by over-temperature, providing great convenience.

Those skilled in the art will readily observe that numerous modifications and alterations of the device and method may be made while retaining the teachings of the invention.

What is claimed is:

1. An over-temperature detecting circuit, comprising:
a band-gap circuit, for generating a temperature-drop-dependent voltage and a reference voltage not varying with temperature;
a transistor, coupled to the band-gap circuit, for generating a temperature-rise-dependent current according to the temperature-drop-dependent voltage;
a resistor, coupled to the transistor, for generating a temperature-rise-dependent voltage according to the temperature-rise-dependent current; and
a comparator, coupled to the band-gap circuit and the resistor, for generating a thermal shutdown signal according to the reference voltage and the temperature-rise-dependent voltage.

2. The over-temperature detecting circuit of claim 1, wherein the comparator comprising:
a positive input, coupled to the band-gap circuit, for receiving the reference voltage;
a negative input, coupled to the resistor, for receiving the temperature-rise-dependent voltage; and
an output, for outputting the thermal shutdown signal;
wherein when the reference voltage exceeds the temperature-rise-dependent voltage, the comparator outputs the thermal shutdown signal at a high voltage level, and when the temperature-rise-dependent voltage exceeds the reference voltage, the comparator outputs the thermal shutdown signal at a low voltage level.

3. The over-temperature detecting circuit of claim 2, wherein when the thermal shutdown signal is at the high voltage level, the operation of a relevant circuit coupled to the over-temperature detecting circuit remains.

4. The over-temperature detecting circuit of claim 2, wherein when the thermal shutdown signal is at the low voltage level, a relevant circuit coupled to the over-temperature detecting circuit is shut down for preventing over-temperature.

5. The over-temperature detecting circuit of claim 2, wherein the transistor comprising:
a first end, coupled to a first bias source;
a control end, coupled to the band-gap circuit, for receiving the temperature-drop-dependent voltage; and
a second end, for outputting the temperature-rise-dependent current;
wherein the transistor outputs the temperature-rise-dependent current at the second end of the transistor according to the temperature-drop-dependent voltage received at the control end of the transistor.

6. The over-temperature detecting circuit of claim 5, wherein the resistor coupled between the second end of the transistor, the negative input of the comparator, and a second bias source.

7. The over-temperature detecting circuit of claim 6, wherein a bias provided by the first bias source is higher than a bias provided by the second bias source.

8. The over-temperature detecting circuit of claim 1, wherein the transistor is a p-channel metal oxide semiconductor (PMOS) transistor.

9. The over-temperature detecting circuit of claim 7, wherein the band-gap circuit comprising:
a first transistor, comprising:
a first end, coupled to the first bias source;
a second end, employed as a first output of the band-gap circuit for outputting the reference voltage; and
a control end;
a second transistor, comprising:
a first end, coupled to the first bias source;
a second end; and
a control end;
a first resistor, coupled to the second end of the first transistor;
an operational amplifier, comprising:
a positive input, coupled to the second end of the second transistor;
a negative input, coupled to the first resistor; and
an output, coupled to the control end of the first transistor and the control end of the second transistor, employed as a second output of the band-gap circuit for outputting the temperature-drop-dependent voltage;
a second resistor, coupled to the positive input of the operational amplifier and the second end of the second transistor;
a third transistor, comprising:
a first end, coupled to the negative input of the operational amplifier and the first resistor;
a second end, coupled to the second bias source; and
a control end, coupled to the second end of the third transistor; and
a fourth transistor, comprising:
a first end, coupled to the second resistor;
a second end, coupled to the second bias source; and
a control end, coupled to the second end of the fourth transistor.

10. The over-temperature detecting circuit of claim 9, wherein the first transistor and the second transistor are p-channel metal oxide semiconductor (PMOS) transistors.

11. The over-temperature detecting circuit of claim 9, wherein the third transistor and the fourth transistor are PNP bipolar junction transistors (BJT).
